(19) United States
(12) Patent Application Publication
(10) Pub. No.: US 2008/0309373 A1
(43) Pub. Date: Dec. 18, 2008

(54) INTEGRATED CIRCUIT DEVICE AND ELECTRONIC INSTRUMENT

(75) Inventors: Keisuke HASHIMOTO, Fujimi (JP); Hiroki MATSUOKA, Fujimi (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/124,700

(22) Filed: May 21, 2008

(30) Foreign Application Priority Data
Jun. 12, 2007 (JP) 2007-155378

(51) Int. Cl. H03K 19/00

(52) U.S. Cl. 326/93

(57) ABSTRACT

An integrated circuit device includes a clock signal supply control circuit that controls a timing when a master clock signal output from an oscillation circuit is supplied to an internal circuit of the integrated circuit device. The clock signal supply control circuit stops supplying the master clock signal to an internal circuit until a count circuit counts clock pulses of the master clock signal up to a predetermined number. The count circuit performs the count operation asynchronously with the master clock signal. The integrated circuit device may include a divided clock signal supply circuit that supplies a divided clock signal obtained by dividing the frequency of a clock signal output from the clock signal supply control circuit to the internal circuit. A clock signal divider circuit generates the divided clock signal asynchronously with the master clock signal.

Japanese Patent Application No. 2007-155378, filed on Jun. 12, 2007, is hereby incorporated by reference in its entirety.

### BACKGROUND OF THE INVENTION

The present invention relates to an integrated circuit device and an electronic instrument.

A microcomputer including a CPU, a RAM, a communication control circuit, and peripheral circuits is incorporated in various battery-driven portable instruments. A reduction in power consumption is desired for battery-driven portable instruments in order to enable continuous operation for a long time. An integrated circuit device (e.g., microcomputer) generally includes circuits (e.g., CPU) for which high-speed operation is required, and peripheral circuits for which high-speed operation is not required. Therefore, it is unnecessary to supply a clock signal with the highest frequency to all circuits. Specifically, a clock signal divider circuit is provided in an integrated circuit device to supply a clock signal with a minimum frequency to each circuit, thereby reducing power consumption. A microcomputer may include an oscillation stabilization wait circuit (count circuit) for stopping the supply of a clock signal to the internal circuit of the microcomputer until clock oscillations become stable after supplying power, for example. JP-A-2003-256068 discloses technology in this field, for example.

According to related-art technology, since a count circuit and a clock signal divider circuit are synchronous circuits that operate based on a high-frequency master clock signal, these circuits consume a large amount of power.

### SUMMARY

According to a first aspect of the invention, there is provided an integrated circuit device operating based on a master clock signal output from an oscillation circuit, the integrated circuit device comprising:

a clock signal supply control circuit that controls a timing when the master clock signal is supplied to an internal circuit of the integrated circuit device,

the clock signal supply control circuit including a count circuit that counts clock pulses of the master clock signal up to a predetermined number, and stopping supplying the master clock signal to the internal circuit until the count circuit counts the clock pulses up to the predetermined number; and

the count circuit performing a count operation asynchronously with the master clock signal.

According to a second aspect of the invention, there is provided an electronic instrument comprising:

the above-described integrated circuit device;

a receiving section that receives input information; and

an output section that outputs a result of a process performed by the integrated circuit device based on the input information.

### BRIEF DESCRIPTION OF THE SEVERAL VIEWS OF THE DRAWING

FIG. 1 is a functional block diagram showing an integrated circuit device according to one embodiment of the invention.

FIG. 2 is a diagram illustrative of a first configuration example of a clock signal supply control circuit included in an integrated circuit device according to one embodiment of the invention.

FIG. 3 shows a timing chart illustrative of the first configuration example of the clock signal supply control circuit.

FIG. 4 is a diagram illustrative of a second configuration example of a clock signal supply control circuit included in an integrated circuit device according to one embodiment of the invention.

FIG. 5 is a diagram illustrative of a third configuration example of a clock signal supply control circuit included in an integrated circuit device according to one embodiment of the invention.

FIG. 6 is a diagram illustrative of a first configuration example of a divided clock signal supply circuit included in an integrated circuit device according to one embodiment of the invention.

FIG. 7 shows a timing chart illustrative of the first configuration example of the divided clock signal supply circuit.

FIG. 8 is a diagram illustrative of a second configuration example of a divided clock signal supply circuit included in an integrated circuit device according to one embodiment of the invention.

FIG. 9 is a diagram illustrative of the configuration of a microcomputer as an example of an integrated circuit device according to one embodiment of the invention.

FIG. 10 is a block diagram showing an example of an electronic instrument including an integrated circuit device (microcomputer).

FIGS. 11A to 11C are outside views showing examples of various electronic instruments.

### DETAILED DESCRIPTION OF THE EMBODIMENT

The invention may provide an integrated circuit device with low power consumption due to incorporation of a count circuit and a clock signal divider circuit that operate asynchronously with a master clock signal, and an electronic instrument.

(1) According to one embodiment of the invention, there is provided an integrated circuit device operating based on a master clock signal output from an oscillation circuit, the integrated circuit device comprising:

a clock signal supply control circuit that controls a timing when the master clock signal is supplied to an internal circuit of the integrated circuit device,

the clock signal supply control circuit including a count circuit that counts clock pulses of the master clock signal up to a predetermined number, and stopping supplying the master clock signal to the internal circuit until the count circuit counts the clock pulses up to the predetermined number; and

the count circuit performing a count operation asynchronously with the master clock signal.

The oscillation circuit may be provided inside or outside of the integrated circuit device.

The count circuit may count the clock pulses of the master clock signal up to the predetermined number after a reset signal has been canceled, for example. The count circuit may count the clock pulses of the master clock signal up to the predetermined number after the operation of the count circuit has been enabled based on a value set in an internal register of the integrated circuit device.

It suffices that the count circuit perform the count operation asynchronously with the master clock signal. The operation of the count circuit other than the count operation may be in synchronization with the master clock signal.

According to this embodiment, the count circuit is not configured as a counter which is completely in synchronization with the master clock signal, but operates asynchronously with the master clock signal. Therefore, since the count circuit need not operate at the frequency of the master clock signal, power consumption when counting an oscillation stabilization wait period can be reduced, for example.

(2) In the integrated circuit in this embodiment, the clock signal supply control circuit may stop the count operation of the count circuit after the count circuit has counted the clock pulses up to the predetermined number.

This makes it possible to stop the operation of the count circuit after the count circuit has completed the count operation. For example, when stopping only the supply of the clock signal when counting the oscillation stabilization wait period after power has been supplied, the count circuit need not perform the count operation after the count circuit has counted the oscillation stabilization wait period. According to this embodiment, power consumption after completion of the count operation can be reduced.

(3) In the integrated circuit in this embodiment, the clock signal supply control circuit may variably control the predetermined number to be counted by the count circuit according to a predetermined condition.

The predetermined condition may be given by a control signal input through an external terminal of the integrated circuit device, a control signal generated based on a value set in an internal register of the integrated circuit device, or a control signal obtained by decoding the value set in the internal register.

According to this embodiment, the count number can be variably set so that the oscillation stabilization wait period becomes shortest corresponding to the frequency of the clock signal and the characteristics of the oscillation circuit. Therefore, a stable clock signal can be quickly supplied to the internal circuit after power has been supplied.

(4) In the integrated circuit in this embodiment,

the count circuit may be an asynchronous ripple-carry counter that includes a plurality of flip-flops connected in series, the master clock signal being supplied to a clock signal input terminal of a flip-flop in a first stage among the plurality of flip-flops.

The flip-flop included in the count circuit may be a D flip-flop, a JK flip-flop, a T flip flop, an RS flip-flop, or the like. The flip-flop included in the count circuit may operate at the rising edge or the falling edge of the input clock signal.

The count completion detection circuit may output a signal at the H level or a signal at the L level when detecting completion of the count operation, for example.

According to this embodiment, since the count circuit is formed as an asynchronous ripple-carry counter, the frequency of the clock signal supplied to the flip-flop in the subsequent stage decreases as compared with the frequency of the clock signal supplied to the flip-flop in the preceding stage. Therefore, the number of flip-flops to which the clock signal is supplied corresponding to each clock pulse of the master clock signal is about two on average, regardless of the number of flip-flops connected in series in the asynchronous counter. Therefore, power consumption during the count operation can be significantly reduced as compared with the case of forming the count circuit as a synchronous counter.

According to this embodiment, the master clock signal is supplied to only the clock signal input terminal of the flip-flop in the first stage of the asynchronous ripple-carry counter. Therefore, only the flip-flop in the first stage is affected by an unstable master clock signal output from the oscillation circuit before stable oscillations are achieved.

(5) In the integrated circuit in this embodiment, the clock signal supply control circuit may includes:

a count completion detection circuit that outputs a count completion detection signal when detecting that the count circuit has counted the clock pulses of the master clock signal up to the predetermined number; and

a clock signal output mask circuit that stops supplying the master clock signal to the internal circuit until the count completion detection circuit outputs the count completion detection signal.

The clock signal output mask circuit may be formed as an AND circuit that outputs a signal set at the L level until completion of the count operation is detected, or may be formed as an OR circuit that outputs a signal set at the H level until completion of the count operation is detected, for example.

(6) In the integrated circuit in this embodiment,

the clock signal supply control circuit may include a clock signal input mask circuit that stops supplying the master clock signal to a clock signal input terminal of a flip-flop in a first stage among the plurality of flip-flops of the count circuit after the count completion detection circuit has output the count completion detection signal.

The clock signal input mask circuit may be formed as an AND circuit that outputs a signal set at the L level when stopping the supply of the clock signal, or may be formed as an OR circuit that outputs a signal set at the H level when stopping the supply of the clock signal, for example.

According to this embodiment, the clock signal is not input to the flip-flop in the first stage of the asynchronous ripple-carry counter after completion of the count operation. Therefore, power consumption after completion of the count operation by the asynchronous counter can be significantly reduced.

(7) In the integrated circuit in this embodiment,

the count circuit may includes a selector that selectively supplies the master clock signal or an output from a flip-flop connected to a front stage of a following flip-flop among the plurality of flip-flops to a clock signal input terminal of the following flip-flop according to a predetermined selection signal.

The predetermined selection signal may be a control signal input through an external terminal of the integrated circuit device, a control signal generated based on an output from an internal register of the integrated circuit device, or a control signal obtained by decoding the output from the internal register.

According to this embodiment, the master clock signal is selectively supplied to the clock signal input terminal of at least one flip-flop of the asynchronous ripple-carry counter. Therefore, the number of flip-flops that operate as the asynchronous ripple-carry counter can be changed by changing the clock signal input to the flip-flop. Specifically, the count number of the asynchronous counter can be changed.

A configuration may also be employed in which the master clock signal is supplied to the clock signal input terminals of all of the flip-flops of the asynchronous ripple-carry counter. According to this configuration, a more appropriate count number can be selected.

According to this embodiment, the count number can be variably set so that the oscillation stabilization wait period becomes shortest corresponding to the frequency of the clock signal and the characteristics of the oscillation circuit. Therefore, a stable clock signal can be quickly supplied to the internal circuit after power has been supplied.

(8) In the integrated circuit in this embodiment, the clock signal supply control circuit may include a clock signal delay circuit that delays the master clock signal and supplies the delayed master clock signal to the clock signal output mask circuit.

According to this embodiment, a situation in which a short clock pulse is output from the clock signal output mask circuit when supplying the clock signal can be prevented by absorbing the phase difference between the master clock signal and the count completion detection signal due to the count operation of the asynchronous counter. This makes it possible to prevent malfunction of the internal circuit due to a short clock pulse.

(9) The integrated circuit in this embodiment may further comprise:

a divided clock signal supply circuit that supplies a divided clock signal obtained by dividing a frequency of a clock signal output from the clock signal supply control circuit to the internal circuit of the integrated circuit device,

the divided clock signal supply circuit including a clock signal divider circuit that generates the divided clock signal asynchronously with the master clock signal.

The divided clock signal supply circuit may supply divided clock signal which differ in dividing ratio to respective internal circuits of the integrated circuit device.

According to this embodiment, since the clock signal divider circuit generates the divided clock signal asynchronously with the master clock signal, power consumption can be significantly reduced as compared with the case of forming the clock signal divider circuit as a synchronous circuit.

(10) In the integrated circuit in this embodiment, the divided clock signal supply circuit may variably control a dividing ratio of the divided clock signal to be supplied to the internal circuit according to a predetermined condition.

The predetermined condition may be given by a control signal input through an external terminal of the integrated circuit device, a control signal generated based on a value set in an internal register of the integrated circuit device, or a control signal obtained by decoding the value set in the internal register.

According to this embodiment, a divided clock signal at an appropriate frequency can be supplied by changing the dividing ratio corresponding to the operation speed of the internal circuit. Therefore, the power consumption of the internal circuit can be minimized.

(11) In the integrated circuit in this embodiment,

the clock signal divider circuit may be an asynchronous ripple-carry circuit that includes a plurality of flip-flops connected in series, the clock signal output from the clock signal supply control circuit being supplied to a clock signal input terminal of a flip-flop in a first stage among the plurality of flip-flops.

The flip-flop included in the clock signal divider circuit may be a D flip-flop, a JK flip-flop, a T flip flop, an RS flip-flop, or the like. The flip-flop included in the clock signal divider circuit may operate at the rising edge or the falling edge of the input clock signal.

According to this embodiment, since the clock signal divider circuit is formed as an asynchronous ripple-carry circuit, the frequency of the clock signal supplied to the flip-flop in the subsequent stage decreases as compared with the frequency of the clock signal supplied to the flip-flop in the preceding stage. Therefore, the number of flip-flops to which the clock signal is supplied corresponding to each clock pulse of the master clock signal is about two on average, regardless of the number of flip-flops connected in series. Therefore, power consumption during the division operation can be significantly reduced as compared with the case of forming the clock signal divider circuit as a synchronous circuit.

(12) In the integrated circuit in this embodiment,

the divided clock signal supply circuit may include a divided clock signal selection circuit that selects one of outputs from at least two flip-flops included in the clock signal divider circuit according to a predetermined selection signal, and supplies the selected output to the internal circuit.

The predetermined selection signal may be a control signal input through an external terminal of the integrated circuit device, a control signal generated based on an output from an internal register of the integrated circuit device, or a control signal obtained by decoding the output from the internal register.

According to this embodiment, the dividing ratio of the divided clock signal supplied to the internal circuit can be changed. The divided clock signal selection circuit may be configured so that the output from an arbitrary flip-flop of the clock signal divider circuit can be selected and supplied to the internal circuit as the divided clock signal. According to this configuration, since a divided clock signal at a more appropriate dividing ratio can be supplied to the internal circuit, power consumption can be minimized.

(13) According to one embodiment of the invention, there is provided an electronic instrument comprising:

the above-described integrated circuit device;

a receiving section that receives input information; and

an output section that outputs a result of a process performed by the integrated circuit device based on the input information.

Some embodiments of the invention will be described in detail below, with reference to the drawings. Note that the embodiments described below do not in any way limit the scope of the invention laid out in the claims herein. In addition, not all of the elements of the embodiments described below should be taken as essential requirements of the invention.

1. Integrated Circuit Device

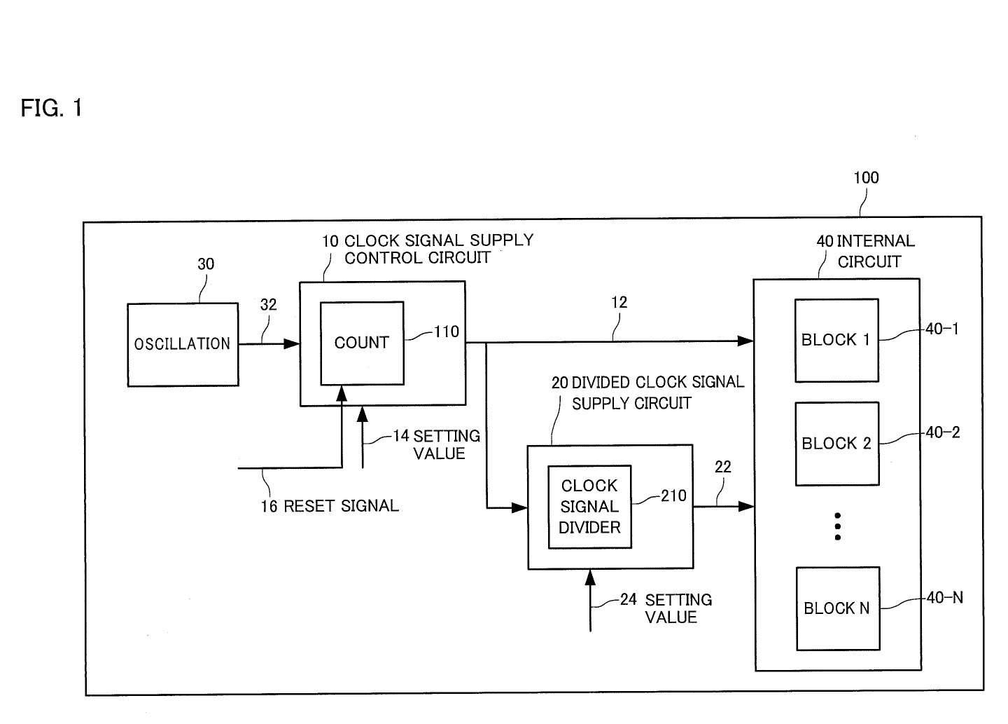

FIG. 1 is a functional block diagram showing an integrated circuit device according to one embodiment of the invention.

An integrated circuit device 100 includes a clock signal supply control circuit 10. The clock signal supply control circuit 10 controls the timing at which a master clock signal 32 output from an oscillation circuit 30 is supplied to an internal circuit 40.

The clock signal supply control circuit 10 includes a count circuit 110. The count circuit 110 counts the clock pulses of the master clock signal 32 until a predetermined number is reached. The clock signal supply control circuit 10 stops supplying the master clock signal 32 to the internal circuit 40 until the count circuit 110 counts the clock pulses of the master clock signal 32 up to the predetermined number. Specifically, the clock signal supply control circuit 10 prevents the master clock signal 32 from being output as an output 12 until the count circuit 110 counts the clock pulses of the master clock signal 32 up to the predetermined number. The count circuit 110 performs the count operation asynchronously with the master clock signal 32.

The oscillation circuit 30 starts to output the master clock signal 32 immediately after power has been supplied to the integrated circuit device 10, for example. The oscillation circuit 30 may be provided inside or outside of the integrated circuit device 100.

When a reset signal 16 is generated when power is supplied to the integrated circuit device 10, the count circuit 110 may count the clock pulses of the master clock signal 32 up to the predetermined number after the reset signal 16 has been canceled. According to this configuration, if the count circuit 110 counts the clock pulses of the master clock signal 32 in a number corresponding to the period of time required for the oscillation circuit 30 to stably output the master clock signal 32 after starting the oscillation operation, the master clock signal 32 is not supplied to the internal circuit 40 until the master clock signal 32 becomes stable. Therefore, a situation in which an unstable clock signal is supplied to the internal circuit 40 so that the internal circuit 40 malfunctions can be reliably prevented.

The clock signal supply control circuit 10 may stop the count operation of the count circuit 110 after the count circuit 110 has counted the clock pulses of the master clock signal 32 up to the predetermined number.

The clock signal supply control circuit 10 may variably control the predetermined number counted by the count circuit 110 based on a setting value 14 (an example of a predetermined condition). The setting value 14 may be a control signal input through an external terminal of the integrated circuit device 100, a value set in an internal register (not shown) of the integrated circuit device 100, or a control signal obtained by decoding the value set in the internal register.

The integrated circuit device 100 may include a divided clock signal supply circuit 20. The divided clock signal supply circuit 20 generates a divided clock signal 22 by dividing the frequency of the clock signal 12 output from the clock signal supply control circuit 10. The divided clock signal supply circuit 20 includes a clock signal divider circuit 210. The clock signal divider circuit 210 generates the divided clock signal 22 asynchronously with the clock signal 12 (master clock signal 32) output from the clock signal supply control circuit 10. The divided clock signal supply circuit 20 may variably control the dividing ratio of the divided clock signal 22 supplied to the internal circuit 40 based on a setting value 24 (an example of a predetermined condition).

The internal circuit 40 is divided into N blocks 1 to N (40-1 to 40-N). The clock signal 12 (master clock signal 32) output from the clock signal supply control circuit 10 or the divided clock signal 22 may be supplied to the blocks 1 to N (40-1 to 40-N). The divided clock signal supply circuit 20 may generate a plurality of divided clock signals 22 at different dividing ratios, and supply the divided clock signals 22 to the blocks 1 to N (40-1 to 40-N).

The integrated circuit device 100 may include a plurality of clock signal supply control circuits 10 and a plurality of divided clock signal supply circuits 20.

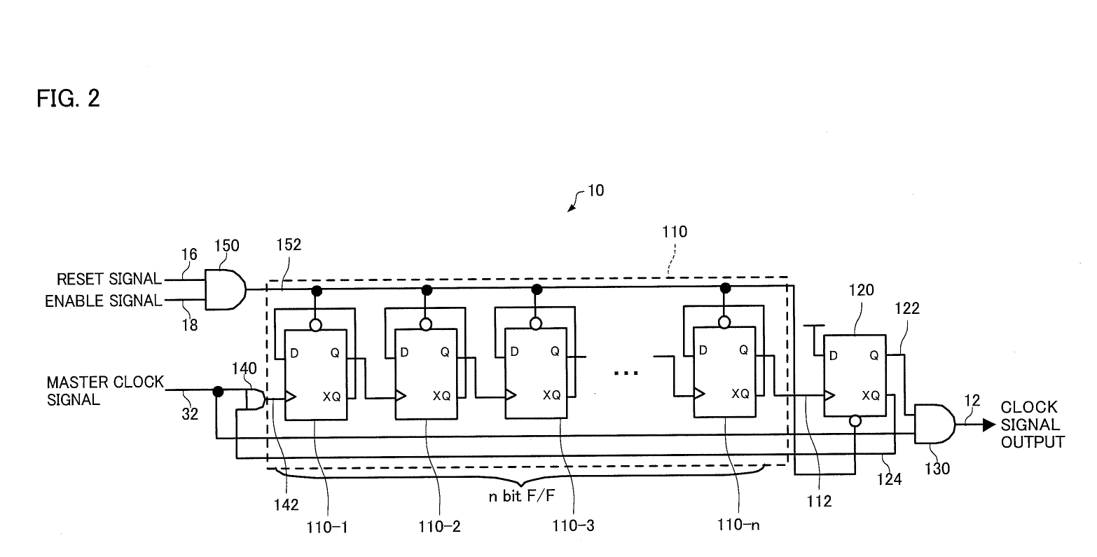

FIG. 2 is a diagram illustrative of a first configuration example of the clock signal supply control circuit included in the integrated circuit device according to this embodiment.

The clock signal supply control circuit 10 includes the count circuit 110. The count circuit 110 is configured as an asynchronous ripple-carry counter which includes n flip-flops 110-1 to 110-n connected in series and in which the master clock signal 32 is supplied to a clock signal input terminal of the flip-flop 110-1 in the first stage. The n flip-flops 110-1 to 110-n are D flip-flops having a low-active set input terminal, a non-inverting output terminal (Q), and an inverting output terminal (XQ), for example. The flip-flops 110-1 to 110-n operate at the rising edge of the input clock signal.

An output 142 from a two-input AND element 140 is supplied to the clock signal input terminal of the flip-flop 110-1 in the first stage. A Q output from the flip-flop 110-k in the kth (k is one of 1 to n−1) stage is supplied to the clock signal input terminal of the flip-flop 110-(k+1) in the (k+1)th stage, and an XQ output from the flip-flop 110-k in the kth stage is supplied to a data input terminal (D) of the flip-flop 110-k in the kth stage. An output 152 from a two-input AND element 150 is supplied in common to the set input terminals of the n flip-flops 110-1 to 110-n. A Q output 112 from the flip-flop 110-n in the final stage (nth stage) is output from the count circuit 110.

Therefore, the count circuit 110 operates so that the Q output 112 from the flip-flop 110-n in the final stage changes from the L level to the H level each time the count circuit 110 counts the clock pulses of the master clock signal 32 2ⁿ times.

A flip-flop 120 functions as a count completion detection circuit which outputs a count completion detection signal when detecting that the count circuit 110 has counted the clock pulses of the master clock signal 32 up to the predetermined number. The flip-flop 120 is a D flip-flop having a low-active reset input terminal, a non-inverting output terminal (Q), and an inverting output terminal (XQ), for example. The flip-flop 120 operates at the rising edge of the input clock signal.

A Q output 112 from the flip-flop 110-n in the final stage of the count circuit 110 is supplied to a clock signal input terminal of the flip-flop 120. A power supply voltage (signal set at the H level) is supplied to a data input terminal (D) of the flip-flop 120. The output 152 from the two-input AND element 150 is supplied to the reset terminal of the flip-flop 120. Specifically, when the output 152 from the two-input AND element 150 is set at the L level, the flip-flop 120 is reset and outputs a signal set at the L level from the Q output terminal. After the reset state of the flip-flop 120 has been canceled (i.e., the output 152 from the two-input AND element 150 has been set at the H level), the flip-flop 120 outputs a signal set at the H level from the Q output terminal at the rising edge of the input clock signal.

Therefore, when the count circuit 110 has counted the clock pulses of the master clock signal 32 2ⁿ times, the flip-flop 120 outputs a signal set at the H level (count completion detection signal) as a Q output 122. The flip-flop 120 successively outputs the count completion detection signal until a signal set at the L level is supplied to the reset input terminal so that the flip-flop 120 is reset.

A two-input AND element 130 functions as a clock signal output mask circuit which stops supplying the master clock signal 32 to the internal circuit 40 (see FIG. 1) until the flip-flop 120 (count completion detection circuit) outputs the count completion detection signal. The master clock signal 32 is supplied to one input terminal of the two-input AND element 130, and the Q output 122 from the flip-flop 120 is supplied to the other input terminal of the two-input AND element 130. Specifically, the two-input AND element 130 outputs the master clock signal 32 when a signal set at the H level is output from the flip-flop 120 as the Q output 122, and outputs a signal set at the L level (stops supplying the master clock signal 32) when a signal set at the L level is output from the flip-flop 120 as the Q output 122. The output from the two-input AND element 130 is the clock signal output 12 from the clock signal supply control circuit 10.

A two-input AND element 140 functions as a clock signal input mask circuit which stops supplying the master clock signal 32 to the clock signal input terminal of the flip-flop 110-1 in the first stage of the count circuit 110 after the flip-flop 120 (count completion detection circuit) has output a signal set at the H level (count completion detection signal) as the Q output 122. The master clock signal 32 is supplied to one input terminal of the two-input AND element 140, and an XQ output 124 from the flip-flop 120 is supplied to the other input terminal of the two-input AND element 140. Specifically, the two-input AND element 140 outputs the master clock signal 32 when a signal set at the H level is output from the flip-flop 120 as the XQ output 124 (i.e., the Q output 122 is set at the L level), and outputs a signal set at the L level (stops supplying the master clock signal 32) when a signal set at the L level is output from the flip-flop 120 as the XQ output 124 (i.e., the Q output 122 is set at the H level).

Since the flip-flop 120 successively outputs a signal set at the H level as the Q output (outputs a signal set at the L level as the XQ output) after the count circuit 110 has counted the clock pulses of the master clock signal 32 2ⁿ times, the two-input AND element 140 also successively outputs a signal set at the L level. Since the output 142 from the two-input AND element 140 is supplied to the clock signal input terminal of the flip-flop 110-1 in the first stage of the count circuit 110, the count circuit 110 stops the count operation after the count circuit 110 has counted the clock pulses of the master clock signal 32 2ⁿ times. Therefore, power consumption due to the count operation of the count circuit 110 can be reduced after the count operation has completed (e.g., after the oscillation stabilization wait period of the oscillation circuit 30 (see FIG. 1) has elapsed).

The two-input AND element 150 supplies an initialization signal 152 to the count circuit 110. The reset signal 16 is supplied to one input terminal of the two-input AND element 150, and an enable signal 18 is supplied to the other input terminal of the two-input AND element 150. For example, the reset signal 16 may be supplied from the outside of the integrated circuit device 10, and the enable signal 18 may be an output from an internal register of the integrated circuit device 10. An L-level pulse of the reset signal 16 is generated when power has been supplied. The reset signal 16 is canceled when the enable signal 18 is set at the H level, and the clock signal supply control circuit 10 outputs a signal set at the L level as the output 12 until the count circuit 110 counts the clock pulses of the master clock signal 32 2ⁿ times. Therefore, the supply of the master clock signal 32 to the internal circuit 40 (see FIG. 1) can be automatically stopped in a specific period (e.g., until the oscillation operation of the oscillation circuit 30 (see FIG. 1) becomes stable) after power has been supplied.

When the value set in the internal register is changed so that the enable signal 18 is set at the L level, the flip-flops 110-1 to 110-n and 120 are initialized so that the output 12 is set at the L level (i.e., clock signal output stops). When the value set in the internal register is changed so that the enable signal 18 is set at the H level, the master clock signal 32 can be output from the clock signal supply control circuit 10 as the output 12 after the count circuit 110 has counted the clock pulses of the master clock signal 32 2ⁿ times. Specifically, the supply of the master clock signal 32 to the internal circuit 40 (see FIG. 1) can be stopped in a specific period by changing the value set in the internal register so that the enable signal 18 changes from the L level to the H level.

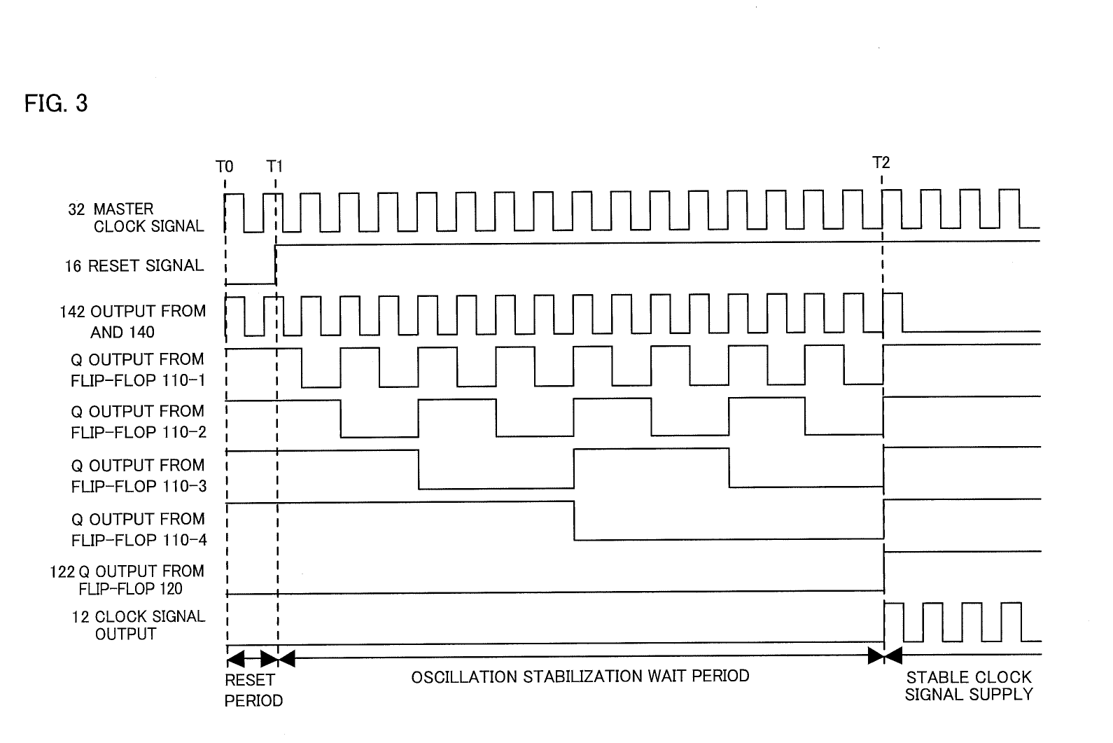

FIG. 3 shows a timing chart illustrative of the first configuration example of the clock signal supply control circuit. FIG. 3 shows a timing chart when the count circuit 110 shown in FIG. 2 includes four (n=4) flip-flops. In FIG. 3, the enable signal 18 shown in FIG. 2 is fixed at the H level. The timing chart shown in FIG. 3 is described below with reference to FIG. 2.

The count circuit 110 does not perform the count operation in a period between times T0 and T1 since the reset signal 16 is set at the L level. Specifically, since the initialization signal 152 is set at the L level, the Q outputs from the flip-flops 110-1 to 110-4 are initialized to the H level, and the Q output 122 from the flip-flop 120 is initialized to the L level. Since the Q output 122 from the flip-flop 120 is set at the L level, the output 12 from the two-input AND element 130 (i.e., the output from the clock signal supply control circuit 10) is fixed at the L level. Since the XQ output 124 from the flip-flop 120 is set at the H level, the master clock signal 32 is output as the output 142 from the two-input AND element 140.

When the reset signal 16 changes from the L level to the H level at the time T1, the count circuit 110 starts the count operation. Specifically, the Q output from the flip-flop 110-1 is reversed at the rising edge of the master clock signal 32 output as the output 142 from the two-input AND element 140. The Q output from the flip-flop 110-2 is reversed at the rising edge of the Q output from the flip-flop 110-1. Likewise, the Q output from the flip-flop 110-3 is reversed at the rising edge of the Q output from the flip-flop 110-2, and the Q output 112 from the flip-flop 110-4 is reversed at the rising edge of the Q output from the flip-flop 110-3. The clock pulses of the master clock signal 32 are thus counted 2⁴ times while the Q outputs from the flip-flops 110-1 to 110-4 are sequentially reversed.

When the clock pulses of the master clock signal 32 have been counted 2⁴ times at a time T2, the Q output 112 from the flip-flop 110-4 changes from the L level to the H level. Therefore, the Q output 122 from the flip-flop 120 changes from the L level to the H level. As a result, the master clock signal 32 is output as the output 12 from the two-input AND element 130 (i.e., the output from the clock signal supply control circuit 10) (i.e., clock signal output starts). When the XQ output 114 from the flip-flop 110-4 changes from the H level to the L level at the time T2, the output 142 from the two-input AND element 140 is fixed at the L level.

Since the Q output 122 from the flip-flop 120 is set at the H level as long as the initialization signal 152 is set at the H level, the master clock signal 32 is successively output as the output 12 from the two-input AND element 130 (i.e., the output from the clock signal supply control circuit 10).

If the oscillation operation of the oscillation circuit 30 (see FIG. 1) has become stable in a period between the times T1 and T2, only a stable clock signal is output from the clock signal supply control circuit 10 as the output 12.

As is clear from the timing chart shown in FIG. 3, the probabilities that the clock signal is supplied to the flip-flops 110-1 to 110-4 at the rising edge of the master clock signal 32 are 1, ½, ¼, and ⅛, respectively. Therefore, the expected value of the total number of flip-flops to which the clock signal is supplied at the rising edge of the master clock signal 32 is 15/8 (=1+½+¼+⅛). Specifically, the clock signal is supplied to about two flip-flops on average at the rising edge of the master clock signal 32.

When forming the count circuit 110 as a synchronous counter, the clock signal is supplied to all of the n flip-flops at the rising edge of the master clock signal 32.

Therefore, power consumption required for the count operation can be significantly reduced by forming the count circuit 110 as an asynchronous ripple-carry counter as compared with the case of forming the count circuit 110 as a synchronous counter.

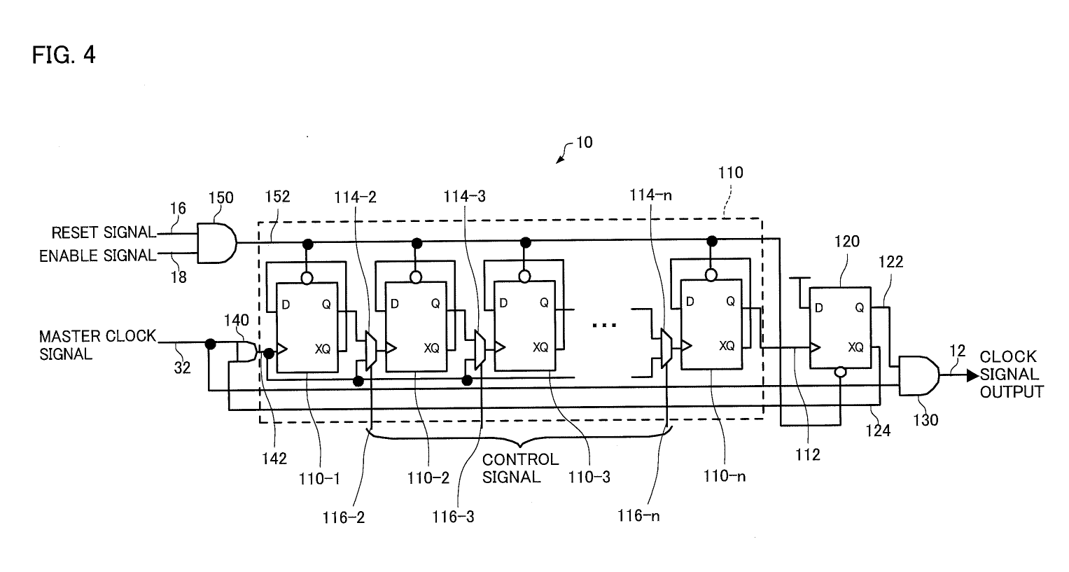

FIG. 4 is a diagram illustrative of a second configuration example of the clock signal supply control circuit included in the integrated circuit device according to this embodiment. The same elements as in FIG. 2 are indicated by the same symbols. Description of these elements is omitted.

In the second configuration example of the clock signal supply control circuit shown in FIG. 4, n−1 2-to-1 selectors 114-2 to 114-n are provided in the count circuit 110 in addition to the configuration shown in FIG. 2. The Q output from the flip-flop 110-(k−1) is supplied to one input terminal of the 2-to-1 selector 114-k (k is one of 2 to n), and the output 142 from the two-input AND element 140 is supplied to the other input terminal of the 2-to-1 selector 114-k. Control signals 116-2 to 116-n are respectively supplied to selection input terminals of the 2-to-1 selectors 114-2 to 114-n. The Q output from the flip-flop 110-(k−1) is selected as the output from the 2-to-1 selector 114-k (k is one of 2 to n) when the control signal 116-k is set at the L level, and the master clock signal 32 is selected as the output from the 2-to-1 selector 114-k when the control signal 116-k is set at the H level. The output from the 2-to-1 selector 114-k is supplied to the clock signal input terminal of the flip-flop 110-k.

The count number of the count circuit 110 can be changed by selecting a control signal set at the H level from the n−1 control signals 116-2 to 116-n. For example, when n is four and the control signals 116-2 to 116-4 are respectively set at the H level, L level, and L level, the count circuit 110 operates as an asynchronous counter which counts the clock pulses of the master clock signal 32 2³ times. Likewise, when the control signals 116-2 to 116-4 are respectively set at the L level, H level, and L level, the count circuit 110 operates as an asynchronous counter which counts the clock pulses of the master clock signal 32 2² times. Specifically, the count number of the count circuit 110 can be changed by changing the settings relating to the control signals 116-2 to 116-n. Therefore, the oscillation stabilization wait period until the master clock signal 32 is output from the clock signal supply control circuit 10 as the output 12 can be arbitrarily adjusted corresponding to the characteristics of the oscillation circuit 30 (see FIG. 1), for example.

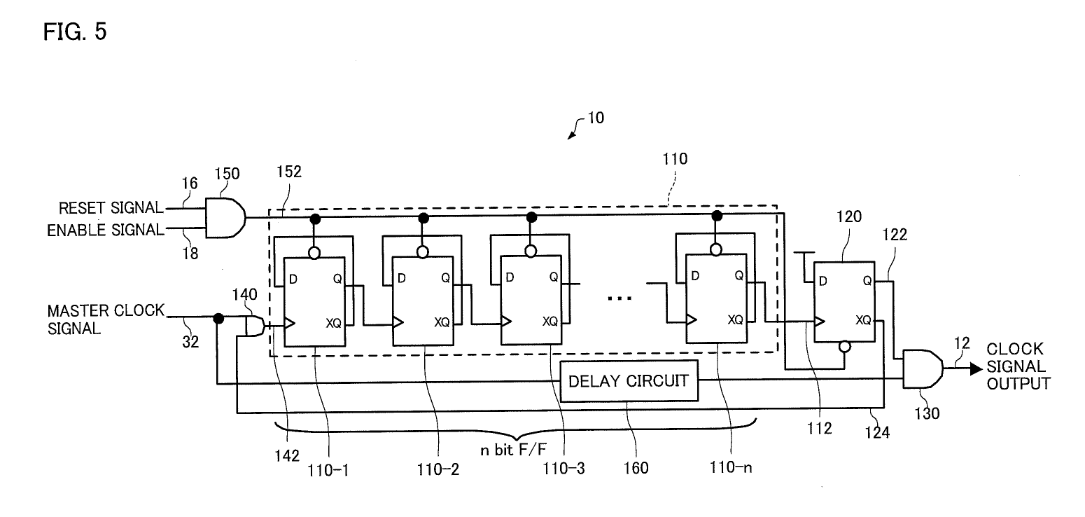

FIG. 5 is a diagram illustrative of a third configuration example of the clock signal supply control circuit included in the integrated circuit device according to this embodiment. The same elements as in FIG. 2 are indicated by the same symbols. Description of these elements is omitted.

In the third configuration example of the clock signal supply control circuit shown in FIG. 5, a delay circuit 160 is provided in addition to the configuration shown in FIG. 2. Since the count circuit 110 is an asynchronous counter, the phase difference between the Q output 112 from the flip-flop 110-n in the final stage and the master clock signal 32 is large. Specifically, the phase difference occurs due to a delay corresponding to the n flip-flops and a delay corresponding to the flip-flop 120 with respect to the output 142 (master clock signal 32) from the two-input AND element 140. As a result, a short pulse may be output from the clock signal supply control circuit 10 as the output 12 when outputting the master clock signal 32, whereby the internal circuit 40 (see FIG. 1) may malfunction. The delay circuit 160 is formed by connecting a plurality of buffers in series, for example. The delay circuit 160 absorbs the above-mentioned delay (phase difference) to prevent a situation in which a short pulse is output from the clock signal supply control circuit 10 as the output 12.

When the count number of the count circuit can be changed as described with reference to FIG. 4, the delay time may be variably controlled by enabling the number of buffers of the delay circuit 160 to be selected.

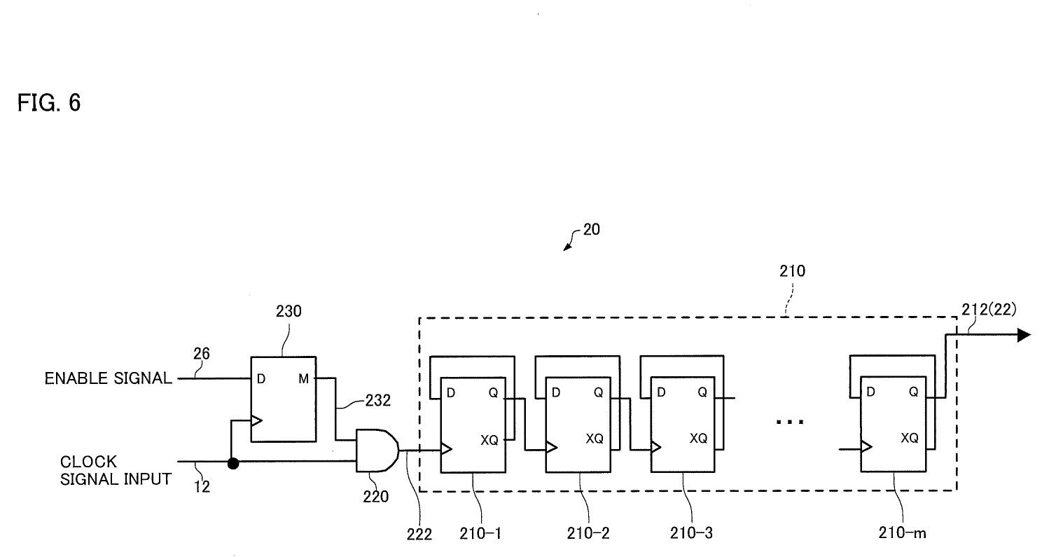

FIG. 6 is a diagram illustrative of a first configuration example of the divided clock signal supply circuit included in the integrated circuit device according to this embodiment.

The divided clock signal supply circuit 20 includes the clock signal divider circuit 210. The divided clock signal supply circuit 20 is configured as an asynchronous ripple-carry circuit which includes m flip-flops 210-1 to 210-m connected in series and in which the clock signal 12 output from the clock signal supply control circuit 10 (see FIG. 1) is supplied to a clock signal input terminal of the flip-flop 210-1 in the first stage. The m flip-flops 210-1 to 210-m are D flip-flops having a non-inverting output terminal (Q) and an inverting output terminal (XQ), for example. The flip-flops 210-1 to 210-m operate at the rising edge of the input clock signal.

An output 222 from a two-input AND element 220 is supplied to the clock signal input terminal of the flip-flop 210-1 in the first stage. A Q output from the flip-flop 210-k in the kth (k is one of 1 to m−1) stage is supplied to the clock signal input terminal of the flip-flop 210-(k+1) in the (k+1)th stage, and an XQ output from the flip-flop 210-k in the kth stage is supplied to a data input terminal (D) of the flip-flop 210-k in the kth stage. A Q output 212 from the flip-flop 210-m in the final stage (mth stage) is output from the clock signal divider circuit 210.

Therefore, the clock signal divider circuit 210 generates a divided clock signal by dividing the frequency of the clock signal 12 by 2^{m}, and outputs the divided clock signal. The output 212 from the clock signal divider circuit 210 is the output (divided clock signal) 22 from the divided clock signal supply circuit.

A flip-flop 230 holds and outputs an enable signal 26 at the rising edge of the clock signal 12. The flip-flop 230 is a D flip-flop having a non-inverting output terminal (M), for example. The flip-flop 230 operates at the rising edge of the input clock signal. The clock signal 12 is supplied to a clock signal input terminal of the flip-flop 230. The enable signal 26 is supplied to a data input terminal (D) of the flip-flop 230.

Therefore, a signal set at the H level is output from the flip-flop 230 as an output 232 at the rising edge of the clock signal 12 when the enable signal 26 is set at the H level. The output 232 from the flip-flop 230 is supplied to one input terminal of a two-input AND element 220. The enable signal 26 may be a signal input through an external terminal of the integrated circuit device 100 (see FIG. 1), a signal generated based on a value set in an internal register of the integrated circuit device 100, or a signal generated by decoding the value set in the internal register.

The two-input AND element 220 stops supplying the clock signal 12 to the clock signal input terminal of the flip-flop 210-1 in the first stage of the clock signal divider circuit 210 when the flip-flop 230 outputs a signal set at the L level as the output 232. The clock signal 12 is supplied to one input terminal of the two-input AND element 220, and the output 232 from the flip-flop 230 is supplied to the other input terminal of the two-input AND element 220. Specifically, the two-input AND element 220 outputs the clock signal 12 when a signal set at the H level is output from the flip-flop 230 as the output 232, and outputs a signal set at the L level (stops supplying the clock signal 12) when a signal set at the L level is output from the flip-flop 230 as the output 232.

Since the output from the two-input AND element 220 is supplied to the clock signal input terminal of the flip-flop 210-1 in the first stage of the clock signal divider circuit 210, the clock signal divider circuit 210 stops the division operation when a signal set at the L level is output from the flip-flop 230 as the output 232. Therefore, when the divided clock signal is unnecessary, power consumption accompanying the division operation of the clock signal divider circuit 210 can be reduced by setting the enable signal 26 at the L level.

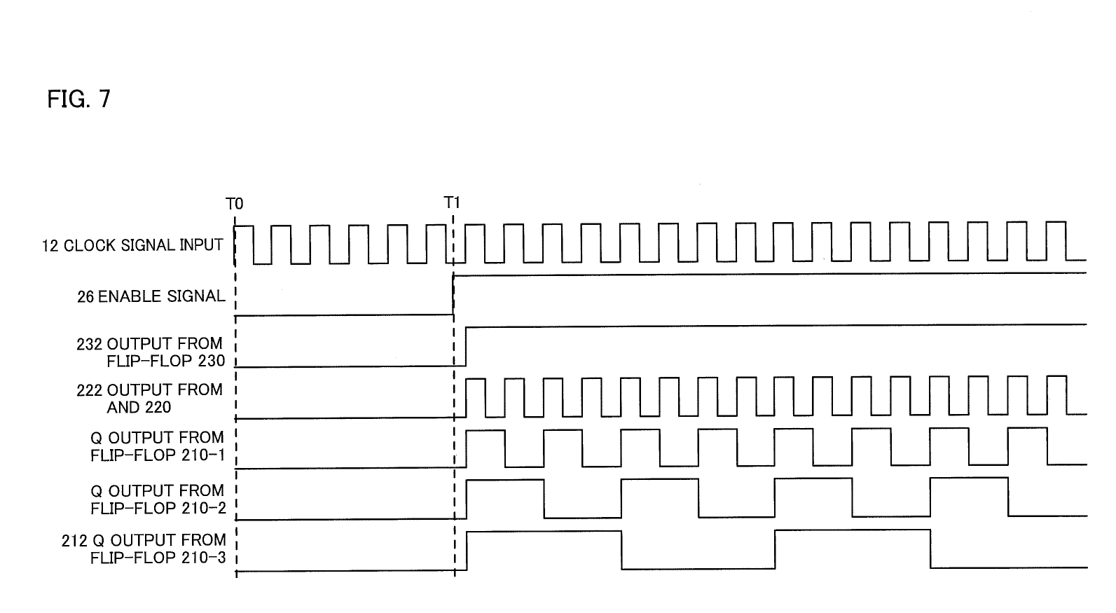

FIG. 7 shows a timing chart illustrative of the first configuration example of the divided clock signal supply circuit. FIG. 7 shows a timing chart when the clock signal divider circuit 210 shown in FIG. 6 includes three (m=3) flip-flops. The timing chart shown in FIG. 7 is described below with reference to FIG. 6.

The clock signal divider circuit 20 does not perform the division operation in a period between times T0 and T1. Specifically, since the enable signal 26 is set at the L level, the output 232 from the flip-flop 230 is set at the L level so that the output 222 from the two-input AND element 220 is set at the L level. Therefore, the clock signal is not input to the flip-flop 210-1 so that the Q output from the flip-flop 210-1 is set at the L level. The Q output of the flip-flop 210-1 is supplied to the clock signal input terminal of the flip-flop 210-2 so that the Q output from the flip-flop 210-2 is set at the L level. Likewise, the Q output of the flip-flop 210-2 is supplied to the clock signal input terminal of the flip-flop 210-3 so that the Q output from the flip-flop 210-3 is set at the L level.

When the enable signal 26 changes from the L level to the H level at the time T1, the clock signal divider circuit 210 starts the division operation. Specifically, the output 232 from the flip-flop 230 is set at the H level at the next rising edge of the clock signal 12 so that the clock signal 12 is output from the two-input AND element 220 as the output 222. The Q output from the flip-flop 210-1 is reversed at the rising edge of the output 222 from the two-input AND element 220 (clock signal 12). The Q output from the flip-flop 210-2 is reversed at the rising edge of the Q output from the flip-flop 210-1. Likewise, the Q output 212 from the flip-flop 210-3 is reversed at the rising edge of the Q output from the flip-flop 210-2. A ½ divided clock signal, a ¼ divided clock signal, and a ⅛ divided clock signal of the clock signal 12 are asynchronously generated while the Q outputs from the flip-flops 210-1 to 210-3 are sequentially reversed.

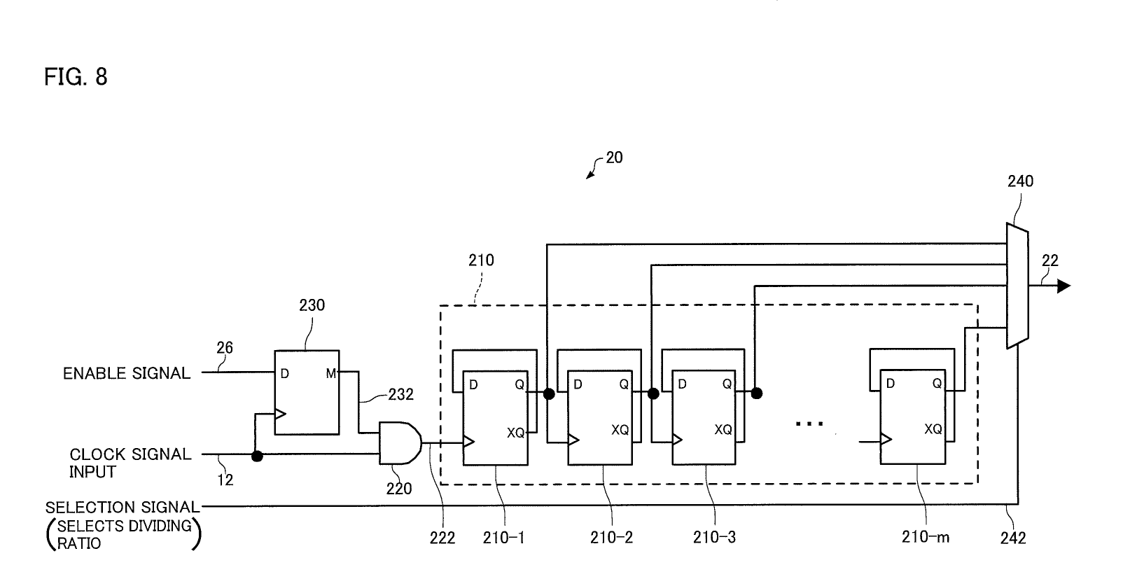

FIG. 8 is a diagram illustrative of a second configuration example of the divided clock signal supply circuit included in the integrated circuit device according to this embodiment. The same elements as in FIG. 6 are indicated by the same symbols. Description of these elements is omitted.

In the second configuration example of the divided clock signal supply circuit shown in FIG. 8, an m-to-1 (m is an integer equal to or larger than two) selector 240 is provided in addition to the configuration shown in FIG. 6. The Q outputs from the flip-flops 210-1 to 210-m are supplied to m input terminals of the m-to-1 selector 240. A selection signal 242 is supplied to a selection input terminal of the m-to-1 selector 240. The output from the m-to-1 selector 240 is the output 22 from the clock signal divider circuit 20.

An arbitrary Q output is selected from the Q outputs from the m flip-flops 210-1 to 210-m according to the selection signal 242, and output as the divided clock signal 22. When the Q output from each of the flip-flops 210-1 to 210-m is selected, a ½ divided clock signal, a ¼ divided clock signal, a ⅛ divided clock signal, . . . , and a ½^{m} divided clock signal are respectively output. Specifically, the divided clock signal supply circuit 20 is configured so that the dividing ratio of the divided clock signal 22 can be variably controlled by changing the selection signal 242.

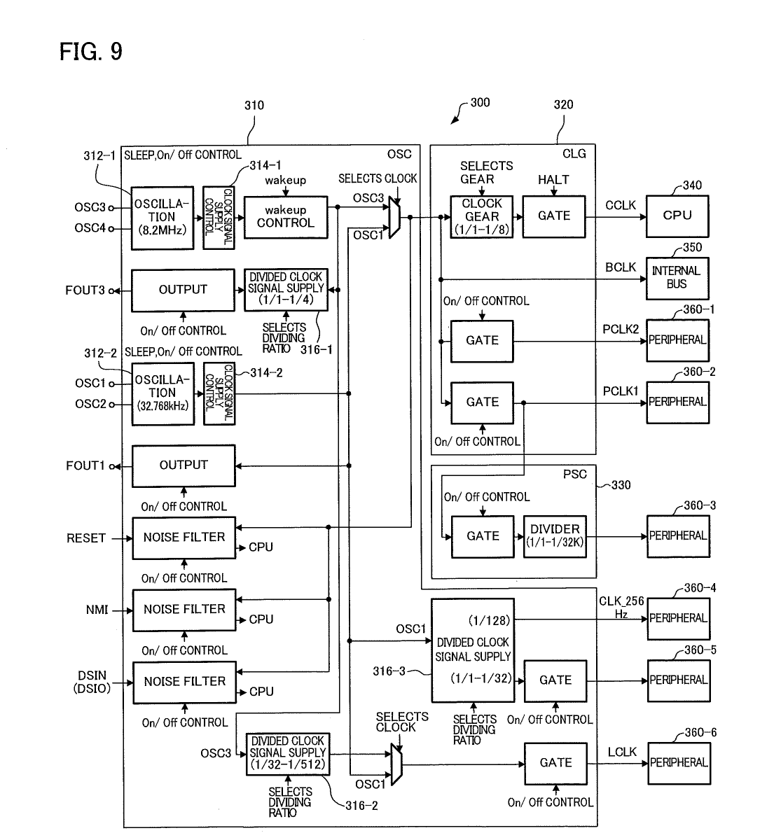

FIG. 9 is a diagram illustrative of the configuration of a microcomputer as an example of the integrated circuit device according to this embodiment.

A microcomputer 300 includes a clock signal generation section (OSC) 310, a clock signal gate section (CLG) 320, a prescaler (PSC) 330, a CPU 340, an internal bus 350, peripheral circuits 1 to 6 (360-1 to 360-6), and the like. Two clock signal supply control circuits 314-1 and 314-2 included in the clock signal generation section (OSC) 310 respectively utilize the outputs from oscillation circuits 312-1 and 312-2 as a master clock signal, and have the configuration described with reference to FIGS. 2, 4, or 5. Specifically, the clock signal supply control circuits 314-1 and 314-2 perform the count operation asynchronously with the master clock signal, and need not operate at the frequency of the master clock signal. Therefore, the microcomputer according to this embodiment can significantly reduce power consumption during the count operations of the clock signal supply control circuits 314-1 and 314-2.

Divided clock signal supply circuits 316-1 and 316-2 generate divided clock signals by using the clock signal output from the clock signal supply control circuit 314-1 as an input. Likewise, a divided clock signal supply circuit 316-3 generates a divided clock signal by using the clock signal output from the clock signal supply control circuit 314-2 as an input. The divided clock signal supply circuits 316-1 to 316-3 have the configuration described with reference to FIGS. 6 or 8, for example. Specifically, the divided clock signal supply circuits 316-1 to 316-3 perform the division operation asynchronously with the clock signals output from the clock signal supply control circuits 314-1 and 314-2, and need not operate at the frequency of the master clock signal. Therefore, the microcomputer according to this embodiment can significantly reduce power consumption during the division operations of the divided clock signal supply circuits 316-1 to 316-3.

2. Electronic Instrument

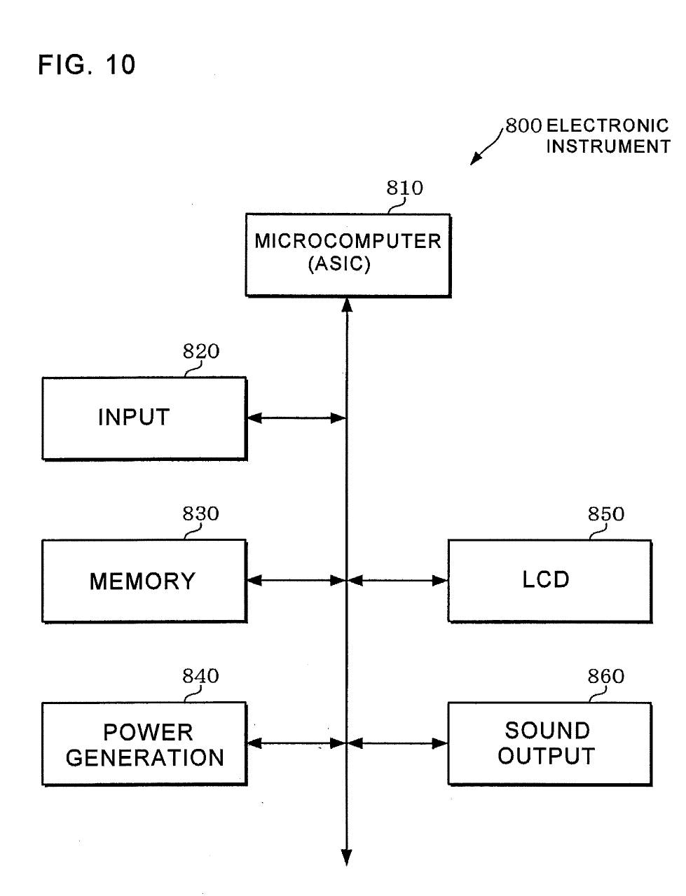

FIG. 10 shows an example of a block diagram of an electronic instrument according to one embodiment of the invention. An electronic instrument 800 includes a microcomputer (integrated circuit device) 810, an input section 820, a memory 830, a power generation section 840, an LCD 850, and a sound output section 860.

The input section 820 is used for inputting various types of data. The microcomputer (integrated circuit device) 810 performs various processes based on data input through the input section 820. The memory 830 functions as a work area for the microcomputer 810 and the like. The power supply generation section 840 generates various power supply voltages used in the electronic instrument 800. The LCD 850 is used for outputting various images (e.g., character, icon, and graphic) displayed by the electronic instrument 800.

The sound output section 860 is used to output various types of sound (e.g., voice and game sound) output from the electronic instrument 800. The function of the sound output section 860 may be implemented by hardware such as a speaker.

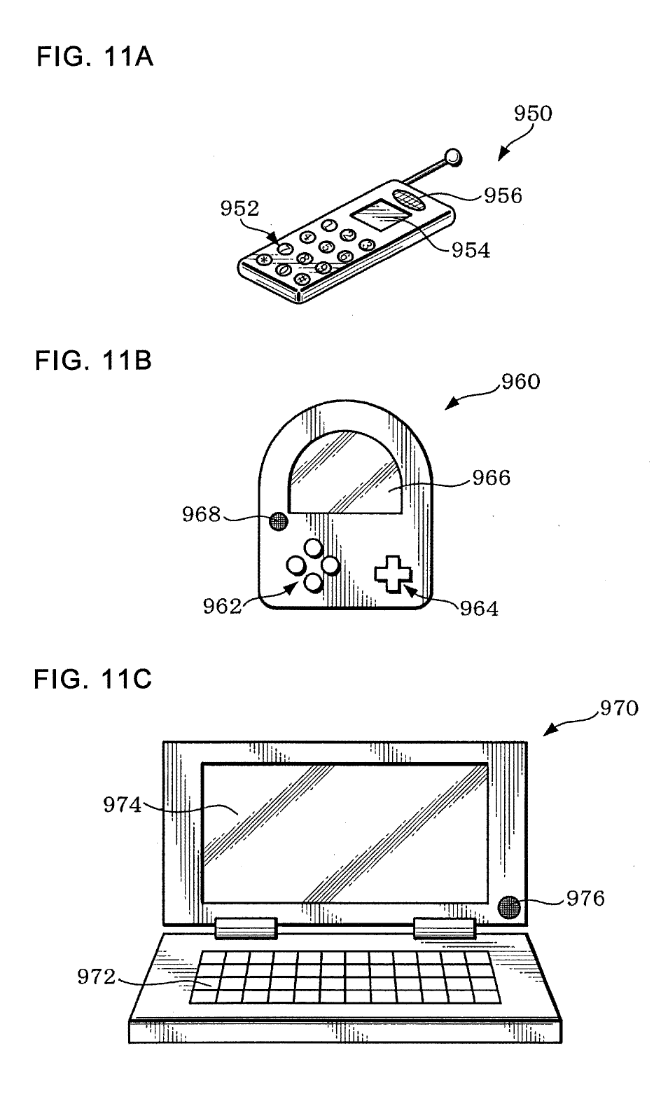

FIG. 11A shows an example of an outside view of a portable telephone 950 which is one type of electronic instrument. The portable telephone 950 includes dial buttons 952 which function as the input section, an LCD 954 which displays a telephone number, a name, an icon, and the like, and a speaker 956 which functions as the sound output section and outputs voice.

FIG 11B shows an example of an outside view of a portable game device 960 which is one type of electronic instrument. The portable game device 960 includes operation buttons 962 which function as the input section, an arrow key 964, an LCD 966 which displays a game image, and a speaker 968 which functions as the sound output section and outputs game sound.

FIG 11C shows an example of an outside view of a personal computer 970 which is one type of electronic instrument. The personal computer 970 includes a keyboard 972 which functions as the input section, an LCD 974 which displays a character, a figure, a graphic, and the like, and a sound output section 976.

A highly cost-effective electronic instrument with low power consumption can be provided by incorporating the microcomputer according to the above embodiment in the electronic instruments shown in FIGS. 11A to 11C.

As examples of the electronic instrument to which this embodiment can be applied, various electronic instruments using an LCD such as a personal digital assistant, a pager, an electronic desk calculator, a device provided with a touch panel, a projector, a word processor, a viewfinder or direct-viewfinder video tape recorder, and a car navigation system can be given in addition to the electronic instruments shown in FIGS. 11A, 11B, and 11C.

The invention is not limited to the above-described embodiments. Various modifications and variations may be made without departing from the scope of the invention.

In the configuration examples of the clock signal supply control circuit described with reference to FIGS. 2, 4, and 5, the two-input AND element 130 is used as the output clock signal mask circuit. Note that a two-input OR element may be used as the output clock signal mask circuit, for example. In this case, the XQ output 124 from the flip-flop 120 is supplied to one input terminal of the two-input OR element, and the master clock signal 32 is supplied to the other input terminal of the two-input OR element. The output from the two-input OR element is set at the H level until the count circuit 110 finishes the count operation and the XQ output from the flip-flop 120 is set at the L level. If the phase difference between the two input signals of the two-input OR element is equal to or less than half the cycle of the master clock signal, a short pulse is not output from the two-input OR element when outputting the clock signal even if the delay circuit 160 described with reference to FIG. 5 is not provided.

In the configuration examples of the clock signal supply control circuit described with reference to FIGS. 2, 4, and 5, the two-input AND element 140 is used as the input clock signal mask circuit. Note that a two-input OR element may be used as the input clock signal mask circuit, for example. In this case, the Q output 122 from the flip-flop 120 is supplied to one input terminal of the two-input OR element, and the master clock signal 32 is supplied to the other input terminal of the two-input OR element.

In the configuration examples of the clock signal supply control circuit described with reference to FIGS. 2, 4, and 5, the n flip-flops 110-1 to 110-n and the flip-flop 120 of the count circuit 110 may be flip-flops which operate at the falling edge of the input clock signal. In this case, power consumption can also be reduced during the count operation of the count circuit 110.

In the configuration examples of the divided clock signal supply circuit described with reference to FIGS. 6 and 8, the m flip-flops 110-1 to 110-m of the clock signal divider circuit 210 may be flip-flops which operate at the falling edge of the input clock signal. In this case, power consumption can also be reduced during the division operation of the clock signal divider circuit 210.

Although only some embodiments of this invention have been described in detail above, those skilled in the art will readily appreciate that many modifications are possible in the embodiments without materially departing from the novel teachings and advantages of this invention. Accordingly, all such modifications are intended to be included within the scope of the invention.

What is claimed is:

1. An integrated circuit device operating based on a master clock signal output from an oscillation circuit, the integrated circuit device comprising:
a clock signal supply control circuit that controls a timing when the master clock signal is supplied to an internal circuit of the integrated circuit device,
the clock signal supply control circuit including a count circuit that counts clock pulses of the master clock signal up to a predetermined number, and stopping supplying the master clock signal to the internal circuit until the count circuit counts the clock pulses up to the predetermined number; and
the count circuit performing a count operation asynchronously with the master clock signal.

2. The integrated circuit device as defined in claim 1,
the clock signal supply control circuit stopping the count operation of the count circuit after the count circuit has counted the clock pulses up to the predetermined number.

3. The integrated circuit device as defined in claim 1,
the clock signal supply control circuit variably controlling the predetermined number to be counted by the count circuit according to a predetermined condition.

4. The integrated circuit device as defined in claim 2,
the clock signal supply control circuit variably controlling the predetermined number to be counted by the count circuit according to a predetermined condition.

5. The integrated circuit device as defined in claim 1,
the count circuit being an asynchronous ripple-carry counter that includes a plurality of flip-flops connected in series, the master clock signal being supplied to a clock signal input terminal of a flip-flop in a first stage among the plurality of flip-flops.

6. The integrated circuit device as defined in claim 2,
the count circuit being an asynchronous ripple-carry counter that includes a plurality of flip-flops connected in series, the master clock signal being supplied to a clock signal input terminal of a flip-flop in a first stage among the plurality of flip-flops.

7. The integrated circuit device as defined in claim 3,
the count circuit being an asynchronous ripple-carry counter that includes a plurality of flip-flops connected in series, the master clock signal being supplied to a clock signal input terminal of a flip-flop in a first stage among the plurality of flip-flops.

8. The integrated circuit device as defined in claim 5,
the clock signal supply control circuit including:
a count completion detection circuit that outputs a count completion detection signal when detecting that the count circuit has counted the clock pulses of the master clock signal up to the predetermined number; and
a clock signal output mask circuit that stops supplying the master clock signal to the internal circuit until the count completion detection circuit outputs the count completion detection signal.

9. The integrated circuit device as defined in claim 6,
the clock signal supply control circuit including:
a count completion detection circuit that outputs a count completion detection signal when detecting that the count circuit has counted the clock pulses of the master clock signal up to the predetermined number; and
a clock signal output mask circuit that stops supplying the master clock signal to the internal circuit until the count completion detection circuit outputs the count completion detection signal.

10. The integrated circuit device as defined in claim 7,
the clock signal supply control circuit including:
a count completion detection circuit that outputs a count completion detection signal when detecting that the count circuit has counted the clock pulses of the master clock signal up to the predetermined number; and
a clock signal output mask circuit that stops supplying the master clock signal to the internal circuit until the count completion detection circuit outputs the count completion detection signal.

11. The integrated circuit device as defined in claim 8,
the clock signal supply control circuit including a clock signal input mask circuit that stops supplying the master clock signal to a clock signal input terminal of a flip-flop in a first stage among the plurality of flip-flops of the count circuit after the count completion detection circuit has output the count completion detection signal.

12. The integrated circuit device as defined in claim 5,
the count circuit including a selector that selectively supplies the master clock signal or an output from a flip-flop connected to a front stage of a following flip-flop among the plurality of flip-flops to a clock signal input terminal of the following flip-flop according to a predetermined selection signal.

13. The integrated circuit device as defined in claim 8,
the count circuit including a selector that selectively supplies the master clock signal or an output from a flip-flop connected to a front stage of a following flip-flop among the plurality of flip-flops to a clock signal input terminal of the following flip-flop according to a predetermined selection signal.

14. The integrated circuit device as defined in claim 8,
the clock signal supply control circuit including a clock signal delay circuit that delays the master clock signal and supplies the delayed master clock signal to the clock signal output mask circuit.

15. The integrated circuit device as defined in claim 1, further comprising:
a divided clock signal supply circuit that supplies a divided clock signal obtained by dividing a frequency of a clock signal output from the clock signal supply control circuit to the internal circuit of the integrated circuit device,
the divided clock signal supply circuit including a clock signal divider circuit that generates the divided clock signal asynchronously with the master clock signal.

16. The integrated circuit device as defined in claim 2, further comprising:
a divided clock signal supply circuit that supplies a divided clock signal obtained by dividing a frequency of a clock signal output from the clock signal supply control circuit to the internal circuit of the integrated circuit device,
the divided clock signal supply circuit including a clock signal divider circuit that generates the divided clock signal asynchronously with the master clock signal.

17. The integrated circuit device as defined in claim 15,
the divided clock signal supply circuit variably controlling a dividing ratio of the divided clock signal to be supplied to the internal circuit according to a predetermined condition.

18. The integrated circuit device as defined in claim 15,
the clock signal divider circuit being an asynchronous ripple-carry circuit that includes a plurality of flip-flops connected in series, the clock signal output from the clock signal supply control circuit being supplied to a clock signal input terminal of a flip-flop in a first stage among the plurality of flip-flops.

19. The integrated circuit device as defined in claim 18,
the divided clock signal supply circuit including a divided clock signal selection circuit that selects one of outputs from at least two flip-flops included in the clock signal divider circuit according to a predetermined selection signal, and supplies the selected output to the internal circuit.

20. An electronic instrument comprising:
the integrated circuit device as defined in claim 1;
a receiving section that receives input information; and
an output section that outputs a result of a process performed by the integrated circuit device based on the input information.
